(19) United States
(12) Patent Application Publication
(10) Pub. No.: US 2025/0070059 A1
(43) Pub. Date: Feb. 27, 2025

(54) CONNECTOR HEIGHT UNIFORMITY OVER UNDER BUMP METAL (UBM)

(71) Applicant: Taiwan Semiconductor Manufacturing Company, Ltd., Hsinchu (TW)

(72) Inventors: Bo-Huan Hsin, Taichung (TW); Ying-Han Chiou, Tainan (TW); Shih-Cheng Chang, Tainan (TW)

(73) Assignee: Taiwan Semiconductor Manufacturing Company, Ltd., Hsinchu (TW)

(21) Appl. No.: 18/456,093

(22) Filed: Aug. 25, 2023

(51) Int. Cl. H01L 23/00; H01L 23/498

(52) U.S. Cl. CPC H01L 24/05; H01L 23/49816; H01L 24/13; H01L 2224/0401; H01L 2224/13007

(57) ABSTRACT

Provided are semiconductor dies and methods for forming semiconductor dies. A method includes forming a semiconductor die having under bump metal (UBM) pads in a dense region and in an isolated region; forming external electrical connectors in contact with the UBM pads; and limiting the external electrical connectors to a pre-selected vertical height.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, such as individually or in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area. These smaller electronic components such as integrated circuit dies may also require smaller packages that utilize less area than packages of the past, in some applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 8 are cross-sectional views of intermediate steps during a process for forming a package structure in accordance with some embodiments.

FIGS. 9-16 are cross-sectional views focused on the formation of a under bump metal (UBM) structure and solder bump during steps of a process for forming a package structure in accordance with some embodiments.

FIG. 17 is a layout view of under bump metal (UBM) structure and solder bump locations in regions of a die in accordance with some embodiments.

FIGS. 18 and 19 are cross-sectional views of the under bump metal (UBM) structure and solder bumps at locations in different regions in FIG. 17.

FIG. 20 is a layout view of under bump metal (UBM) structure and solder bump locations in regions of a die in accordance with some embodiments.

FIGS. 21-23 are cross-sectional views of the under bump metal (UBM) structure and solder bumps at locations in different regions in FIG. 20.

FIG. 24 is a layout view of under bump metal (UBM) structure and solder bump locations in regions of a die in accordance with some embodiments.

FIG. 25 is a layout view of shapes of under bump metal (UBM) structures in accordance with some embodiments.

FIG. 26 is a flow chart of a method in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. As used herein, “directly over” refers to a vertical alignment of features such that when an overlying feature that is directly over an underlying feature, a vertical axis passes through both features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “directly over”, “over”, “overlying”, “above”, “upper”, “top”, “under”, “underlying”, “beneath”, “below”, “lower”, “bottom”, “side”, “positive slope” and “negative slope” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

All numbers in this description indicating amounts, ratios of materials, physical properties of materials, and/or use are to be understood as modified by the word “about,” except as otherwise explicitly indicated. When modifying a numerical value in the specification or claims, “about” denotes an interval of accuracy, familiar and acceptable to a person skilled in the art. In general, such interval of accuracy is +ten percent. Thus, “about ten” means nine to eleven.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, well-known techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Embodiments discussed herein may be discussed in a specific context, namely a package structure with a fan-out or fan-in wafer-level package. Other embodiments contemplate other applications, such as different package types or different configurations that would be readily apparent to a person of ordinary skill in the art upon reading this disclosure. It should be noted that embodiments discussed herein may not necessarily illustrate every component or feature that may be present in a structure. For example, multiples of a component may be omitted from a figure, such as when discussion of one of the component may be sufficient to convey aspects of the embodiment. Further, method embodiments discussed herein may be discussed as being performed in a particular order; however, other method embodiments may be performed in any logical order.

In embodiments herein, external electrical connectors (i.e., bumps) are formed in dense regions and in isolated regions with a uniform height despite the tendency of such bumps to be formed with different heights, i.e., greater heights in isolated regions and lower heights in dense regions. This may be achieved in two ways. First, the UBM pads in isolated regions may be formed with larger critical dimension than those in dense regions. As a result, bumps formed over the UBM pads in isolated regions are formed with lower heights-similar to or the same as in dense regions. Second, dummy UBM pads may be formed in isolated regions to effectively increase the pad and bump density in such regions. As a result, bumps are formed with a uniform height across both dense and isolated regions.

Thus, embodiments herein provide for forming external electrical connectors over Under Bump Metallizations or Under Ball Metallizations (UBMs) with improved height uniformity across dense and isolated regions of semiconductor dies. The external electrical connectors may include low-temperature reflowable material, such as solder, such as a lead-free solder. In some embodiments, the external electrical connectors are ball grid array (BGA) balls, controlled collapse chip connection (C4) bumps, microbumps, or the like, or metal pillars. For example, embodiments herein counteract the tendency for forming external electrical connectors in dense external electrical connector regions with a lower height than external electrical connectors in isolated external electrical connector regions during processes for forming external electrical connectors across both regions. In some embodiments, UBMs, and the external electrical connectors formed thereon, in dense regions are formed with a first critical dimension; and UBMs, and the external electrical connectors formed thereon, in isolated regions are formed with a second critical dimension greater than the first critical dimension. In some embodiments, dummy UBMs are formed near isolated active UBMs to reduce the relative isolation of such isolated active UBMs. As a result, external electrical connector formation over the active and dummy UBMs proceed in a same or more similar fashion, resulting in external electrical connectors with a same, more similar, or uniform height.

FIGS. 1 through 8 illustrate cross-sectional views of intermediate steps during a process for forming a package structure 100 in accordance with some embodiments. FIG. 1 illustrates a carrier substrate 20 and a release layer 22 formed on the carrier substrate 20. The carrier substrate 20 may be a glass carrier substrate, a ceramic carrier substrate, or the like. The carrier substrate 20 may be a wafer. The release layer 22 may be formed of a polymer-based material, which may be removed along with the carrier substrate 20 from the overlying structures that will be formed in subsequent steps. In some embodiments, the release layer 22 is an epoxy-based thermal-release material, which loses its adhesive property when heated, such as a Light-to-Heat-Conversion (LTHC) release coating. In other embodiments, the release layer 22 may be an ultra-violet (UV) glue, which loses its adhesive property when exposed to UV lights. The release layer 22 may be dispensed as a liquid and cured, may be a laminate film laminated onto the carrier substrate 20, or may be the like. An adhesive 24 can be formed or dispensed on the release layer 22. The adhesive 24 can be a die attach film (DAF), a glue, a polymer material, or the like.

Integrated circuit die 26 is adhered to the carrier substrate 20 (e.g., through the release layer 22) by the adhesive 24. As illustrated, one integrated circuit die 26 is adhered, and in other embodiments, more integrated circuit dies may be adhered. Before being adhered to the carrier substrate 20, the integrated circuit die 26 may be processed according to applicable manufacturing processes to form an integrated circuit in the integrated circuit die 26. For example, the integrated circuit die 26 comprises a bulk semiconductor substrate, a semiconductor-on-insulator (SOI) substrate, multi-layered or gradient substrates, or the like. The semiconductor of the substrate may include any semiconductor material, such as elemental semiconductor like silicon, germanium, or the like; a compound or alloy semiconductor including SiC, GaAs, GaP, InP, InAs, indium antimonide, SiGe, GaAsP, AlInAs, AlGaAs, GalnAs, GalnP, and/or GaInAsP; the like; or combinations thereof. Devices, such as transistors, diodes, capacitors, resistors, etc., may be formed in and/or on the semiconductor substrate and may be interconnected by interconnect structures formed by, for example, metallization patterns in one or more dielectric layers on the semiconductor substrate to form an integrated circuit.

The integrated circuit die 26 further comprises pads 28, such as aluminum pads, to which external connections are made. The pads 28 are on what may be referred to as an active side of the integrated circuit die 26. A passivation film 30 is on the integrated circuit die 26 and on portions of the pads 28. Openings are through the passivation film 30 to the pads 28. Die connectors 32, such as conductive pillars (for example, comprising a metal such as copper), are in the openings through passivation film 30 and are mechanically and electrically coupled to the respective pads 28. The die connectors 32 may be formed by, for example, plating or the like. The die connectors 32 electrically couple the integrated circuit of the integrate circuit die 26. One pad 28 and one die connector 32 are illustrated on the integrated circuit die 26 for clarity and simplicity, and one of ordinary skill in the art will readily understand that more than one pad 28 and more than one die connector 32 may be present.

A dielectric material 34 is on the active side of the integrated circuit die 26, such as on the passivation film 30 and the die connectors 32. The dielectric material 34 laterally encapsulates the die connectors 32, and the dielectric material 34 is laterally co-terminus with the integrated circuit die 26. The dielectric material 34 may be a polymer, such as polybenzoxazole (PBO), polyimide, benzocyclobutene (BCB), or the like. In other embodiments, the dielectric material 34 is formed of a nitride such as silicon nitride; an oxide such as silicon oxide, PhosphoSilicate Glass (PSG), BoroSilicate Glass (BSG), Boron-doped PhosphoSilicate Glass (BPSG), or the like; or the like. The dielectric material 34 may be formed by any acceptable deposition process, such as spin coating, chemical vapor deposition (CVD), laminating, the like, or a combination thereof. The integrated circuit die 26 may be singulated, such as by sawing or dicing, and adhered to the carrier substrate 20 by the adhesive 24 using, for example, a pick-and-place tool.

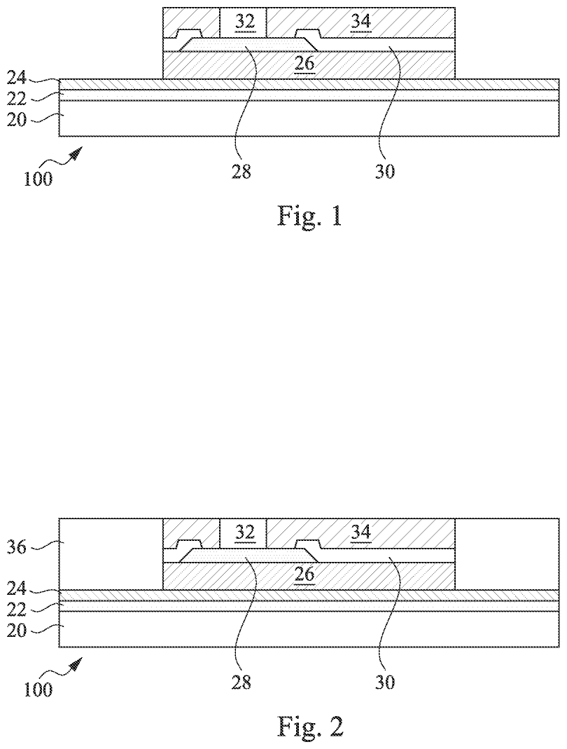

In FIG. 2, an encapsulant 36 is formed on the adhesive 24 around the integrated circuit die 26 and/or on the various components on the integrated circuit die 26. The encapsulant 36 may be a molding compound, epoxy, or the like, and may be applied by compression molding, transfer molding, or the like. After curing, the encapsulant 36 can undergo a grinding process to expose the die connectors 32. Top surfaces of the die connectors 32, dielectric material 34, and encapsulant 36 are co-planar after the grinding process. In some embodiments, the grinding may be omitted, for example, if the die connectors 32 are already exposed.

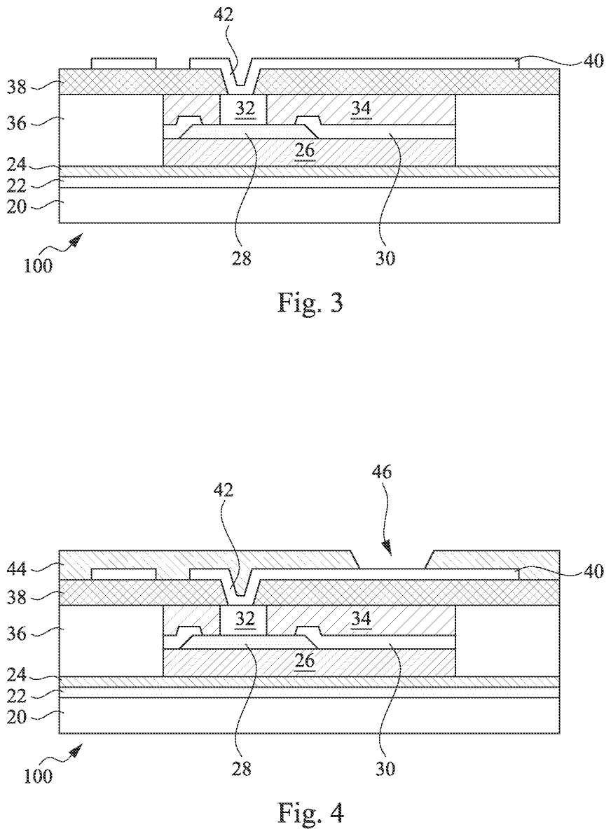

In FIG. 3, a dielectric layer 38 and metallization pattern 40 of a redistribution structure are formed. FIG. 3 and figures that follow illustrate an example configuration of the redistribution structure, and in other embodiments, the redistribution structure can comprise any number of dielectric layers, metallization patterns, and vias.

The dielectric layer 38 is formed on the encapsulant 36, the dielectric material 34, and the die connectors 32. In some embodiments, the dielectric layer 38 is formed of a polymer, which may be a photo-sensitive material such as PBO, polyimide, BCB, or the like, that may be easily patterned using a lithography mask. In other embodiments, the dielectric layer 38 is formed of a nitride such as silicon nitride; an oxide such as silicon oxide, PSG, BSG, BPSG; or the like. The dielectric layer 38 may be formed by spin coating, lamination, CVD, the like, or a combination thereof. The dielectric layer 38 is then patterned to form openings to expose portions of the die connectors 32. The patterning may be by an acceptable process, such as by exposing the dielectric layer 38 to light when the dielectric layer is a photo-sensitive material or by etching using, for example, an anisotropic etch.

The metallization pattern 40 with vias 42 is formed on the dielectric layer 38. As an example to form the metallization pattern 40 and vias 42, a seed layer (not shown) is formed over the dielectric layer 38. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, Physical Vapor Deposition (PVD) or the like. A photo resist is then formed and patterned on the seed layer. The photo resist may be formed by spin coating or the like and may be exposed to light for patterning. The pattern of the photo resist corresponds to the metallization pattern 40. The patterning forms openings through the photo resist to expose the seed layer. A conductive material is formed in the openings of the photo resist and on the exposed portions of the seed layer. The conductive material may be formed by plating, such as electroplating or electroless plating, or the like. The conductive material may comprise a metal, like copper, titanium, tungsten, aluminum, or the like. Then, the photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as by wet or dry etching. The remaining portions of the seed layer and conductive material form the metallization pattern 40 and vias 42. The vias 42 are formed in openings through the underlying layer, e.g., the dielectric layer 38.

One or more additional metallization patterns with vias and dielectric layers may be formed in the redistribution structure by repeating the processes for forming the dielectric layer 38 and the metallization pattern 40. The vias may be formed during the formation of a metallization pattern as discussed. The vias may therefore interconnect and electrically couple the various metallization patterns. The depiction of one dielectric layer, e.g., the dielectric layer 38, and one metallization pattern, e.g., the metallization pattern 40, is for case and simplicity of illustration.

In FIG. 4, a dielectric layer 44 is formed on the metallization pattern 40 and the dielectric layer 38. In some embodiments, the dielectric layer 44 is formed of a polymer, which may be a photo-sensitive material such as PBO, polyimide, BCB, or the like, that may be easily patterned using a lithography mask. In other embodiments, the dielectric layer 44 is formed of a nitride such as silicon nitride; an oxide such as silicon oxide, PSG, BSG, BPSG; or the like. The dielectric layer 44 may be formed by spin coating, lamination, CVD, the like, or a combination thereof. The dielectric layer 44 is then patterned to form openings 46 to expose portions of the metallization pattern 40. The patterning may be by an acceptable process, such as by exposing the dielectric layer 44 to light when the dielectric layer is a photo-sensitive material or by etching using, for example, an anisotropic etch. In FIG. 4, a single opening 46 is formed; however, and number of suitable openings 46. For example, in FIGS. 6 through 8 two openings 46 are illustrated.

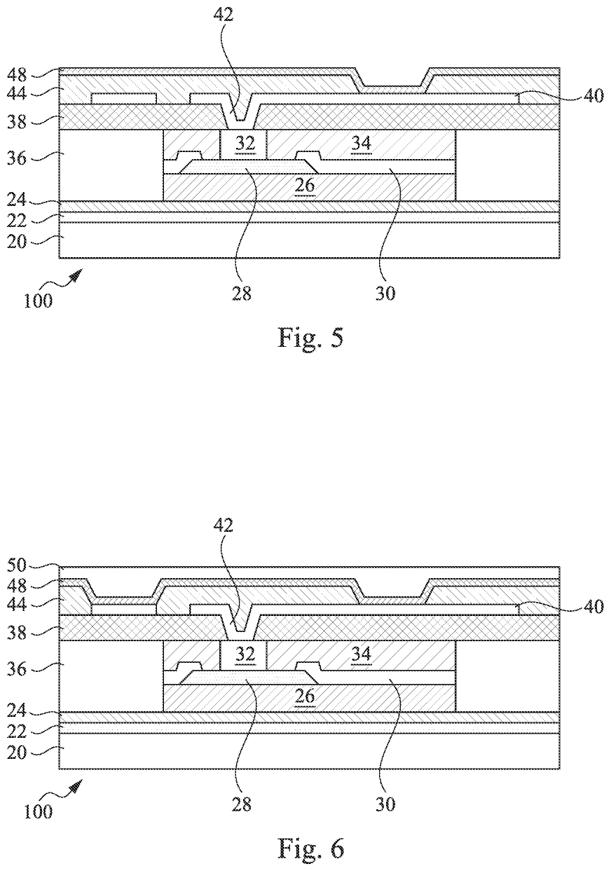

FIGS. 5 through 8 illustrate formation of Under Ball Metallizations (UBMs) 56 for connection to external electrical connectors, described in later Figures.

In FIG. 5, a seed layer 48 is formed over the dielectric layer 44 and in the opening 46, e.g., on sidewalls of the dielectric layer 44 and on the metallization pattern 40. In some embodiments, the seed layer 48 is a metal layer, which may be a single layer or a composite layer comprising a plurality of sub-layers formed of different materials. In some embodiments, the seed layer 48 comprises a titanium layer and a copper layer over the titanium layer. The seed layer 48 may be formed using, for example, PVD or the like.

It is noted that in FIGS. 4 and 5, a single opening 46 is illustrated; however, any number of suitable openings 46 may be formed. For example, in FIGS. 6 through 8 two openings 46 are illustrated.

In FIG. 6, a photo resist 50 is formed on the seed layer 48. In this embodiment, the photo resist 50 is a negative tone photo resist material. The photo resist 50 may be formed on the seed layer by spin coating or the like.

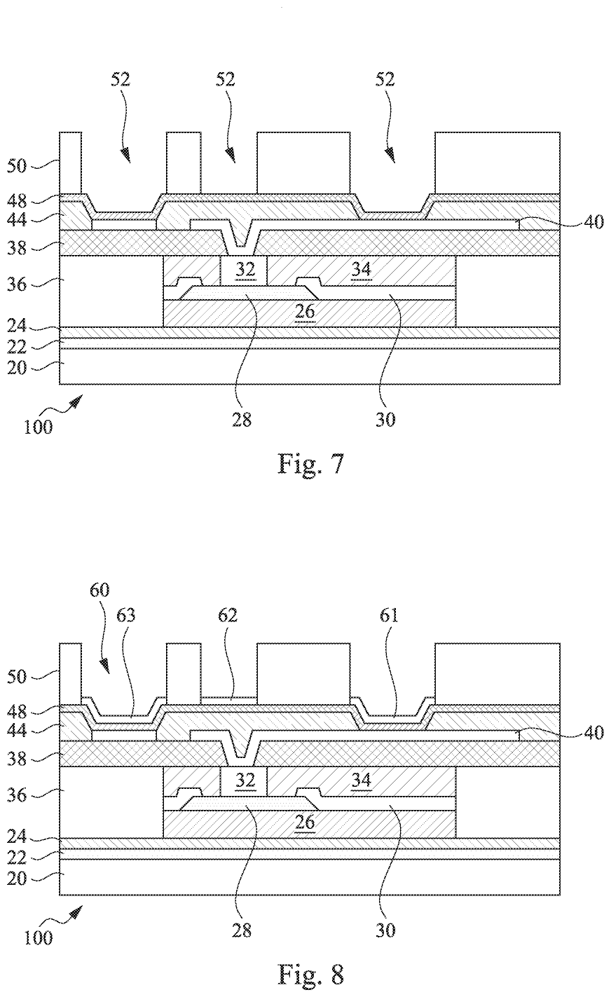

In FIG. 7, the photo resist 50 is patterned on the seed layer 48. The photo resist 50 may be exposed to light and subsequently developed for patterning. Using a negative tone photo resist, portions of the photo resist 50 that are exposed to the light remain after the patterning. After the exposure to light, the photo resist 50 is developed to remove soluble portions of the photo resist 50 such that the non-soluble portions of the photo resist 50 remain on the seed layer 48 with openings 52 through the photo resist 50. The pattern of the photo resist 50 corresponds to the UBMs 60 or other metallization patterns that will be formed.

In FIG. 8, UBMs 60 are formed in respective openings 52 of the photo resist 50 and on the seed layer 48. A conductive material is formed in the openings 52 of the photo resist 50 and on the exposed portions of the seed layer 48, such as by plating, such as electroplating or electroless plating, or the like. The conductive material may comprise a metal, like copper, titanium, tungsten, aluminum, or the like.

FIGS. 1-8 illustrate the formation of three UBMs 60 over a semiconductor die 26: active UBM 61, dummy UBM 62, and dummy UBM 63. After further processing, the seed layer 48 underlying the UBMs 60 will be etched into distinct segments insulated from one another. Specifically, the portions of the seed layer 48 not covered by a UBM 60 will be removed. As shown, UBM 61 is electrically connected to the active side of the integrated circuit die 26 through a pad 28, die connectors 32 through via 42, metallization pattern 40 and seed layer 48. Dummy UBM 62 is formed on a portion of seed layer 48 that lies over dielectric layer 44 and, after etching, is disconnected from any electric path. Dummy UBM 63 is formed on a portion of seed layer 48 that lies over a portion of metallization pattern 40 that, after etching, is disconnected from any electric path.

While FIGS. 1-8 illustrate formation of UBMs 60 at the level over seed layer 48, in other embodiments, the UBMs 60 may be formed at higher or lower levels. For example, FIGS. 1-8 illustrate the formation of two dielectric layers 34 and 44 and a metallization pattern 40 and vias 42. However, additional dielectric layers and upper metallization patterns and via may be formed, with the UBMs 60 formed over the upper metallization patterns. Or, UBMs 60 may be formed on pads 28 at a lower level.

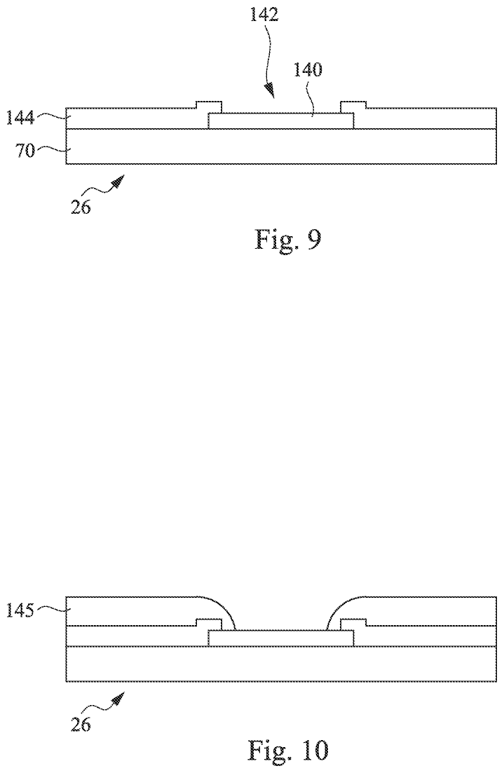

Referring now to FIGS. 9-16, focused views of UBMs 160 during processing of a semiconductor die 26 are provided. In FIGS. 9-16, the UBMs 160 are formed on conductive contacts 140. The UBMs 160 may be formed according to the processes described in relation to FIGS. 1-8, such that the conductive contacts 140 are formed by metallization pattern 40. Alternatively, the conductive contacts 140 may be pads 28 as described in FIGS. 1-8, or the conductive contacts 140 may be formed by a higher metallization level (not illustrated in FIGS. 1-8).

In FIGS. 9-16, the underlying structures of FIGS. 1-8 below conductive contacts 140 are collectively and generally indicated by reference number 70, and may include a conductive interconnect structure extending through various dielectric layers or structures.

As shown in FIG. 9, a passivation layer 144 is formed on the integrated circuit die 26 and on portions of the conductive contacts 140. Openings 142 are formed through the passivation layer 144 to the conductive contacts 140.

In FIG. 10, an insulating material 145 is formed on the active side of the integrated circuit die 26, such as on the passivation layer 144. The insulating material 145 may be a polymer, such as polybenzoxazole (PBO), polyimide, benzocyclobutene (BCB), or the like. In other embodiments, the insulating material 145 is formed of a nitride such as silicon nitride; an oxide such as silicon oxide, PhosphoSilicate Glass (PSG), BoroSilicate Glass (BSG), Boron- doped PhosphoSilicate Glass (BPSG), or the like; or the like. The insulating material 145 may be formed by any acceptable deposition process, such as spin coating, chemical vapor deposition (CVD), laminating, the like, or a combination thereof.

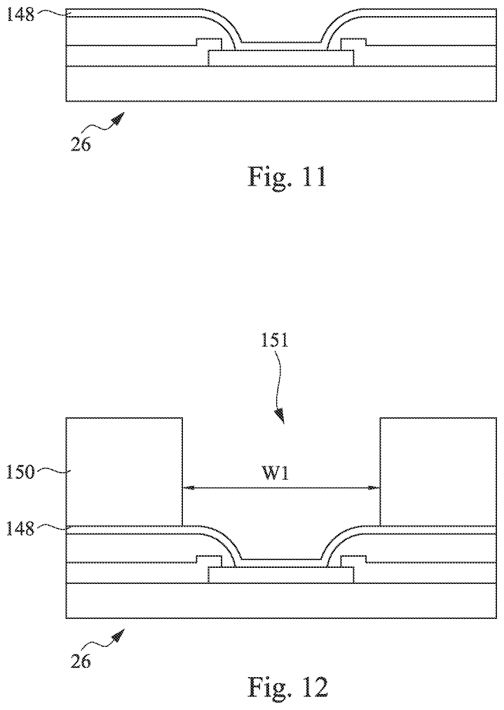

In FIG. 11, a conductive material 148 is then formed over the conductive contacts 140 and insulating material 145, such as by sputtering. The conductive material 148 may comprise a metal, like copper, titanium, tungsten, aluminum, or the like. The conductive material 148 may be a seed layer.

As shown in FIG. 12, photo resist 150 is then formed on the conductive material 148 and patterned. The photo resist 150 may be formed by spin coating or the like and may be exposed to light for patterning. The pattern of the photo resist corresponds to the metallization pattern conductive contacts 140. The patterning forms openings 151 through the photo resist 150 to expose the conductive material 148. As shown, the openings 151 are formed with a lateral width W1 or critical dimension.

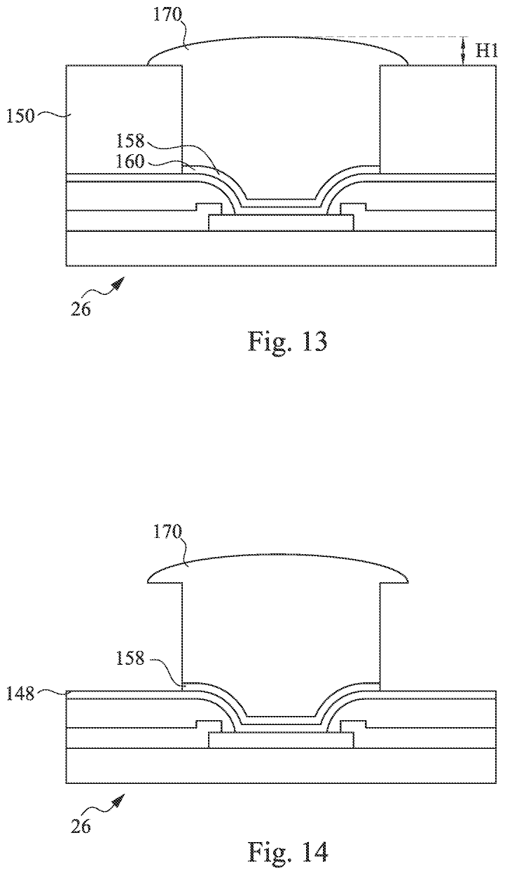

In FIG. 13, a conductive material 158 is formed in the openings of the photo resist 150 and on the exposed portions of the conductive material 148. The conductive material 158 may be formed by plating, such as electroplating or electroless plating, or the like. The conductive material 158 may comprise a metal, like nickel, tin, silver, copper, titanium, tungsten, aluminum, or the like. In some embodiments, the conductive material 158 is a nickel or tin and silver alloy. The conductive material 158 may form and define a UBM structure 160 or pad, or the UBM structure 160 may include the conductive material 158 and the conductive material 148.

Further, in FIG. 13, external electrical connectors 170 are formed on the UBM structures 160 through the openings in the photo resist 150. In some embodiments, the external electrical connectors 170 can include low-temperature reflowable material, such as solder, such as a lead-free solder, formed on the UBMs 160 using an acceptable ball drop process. In some embodiments, the external electrical connectors 170 are ball grid array (BGA) balls, controlled collapse chip connection (C4) bumps, microbumps, or the like. In additional embodiments, the external electrical connectors 170 can include metal pillars.

As shown in FIG. 13, the external electrical connectors 170 are formed with an uppermost surface at a height H1 over the uppermost surface of the photo resist 150.

In FIG. 14, the photo resist 150 is removed. The photo resist may be removed by an acceptable ashing or stripping process, such as using an oxygen plasma or the like.

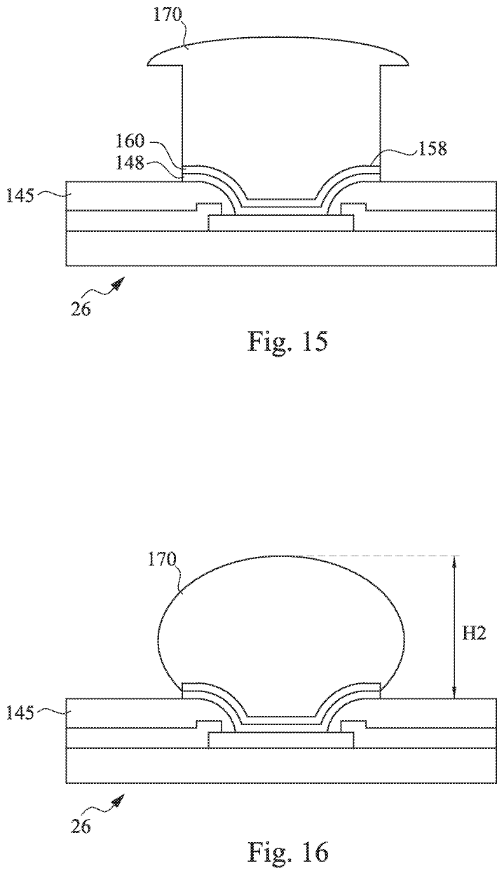

After the photo resist 150 is removed, exposed portions of the conductive material 148 are removed, as shown in FIG. 15. The exposed portions of the conductive material 148 may be removed by using an acceptable etching process, such as by wet or dry etching. The remaining portions of the conductive material 148 and conductive material 158 may form the UBM structure 160. Cross-referencing FIGS. 12 and 15, the UBM structure 160 is formed with the lateral width or critical dimension W1.

In FIG. 16, a reflow process is performed, and the material of the external electrical connectors 170 is reformed. The reflow process may be used to form a metallic interconnect phase between UBM structure 160 and the material of the external electrical connectors 170. In some embodiments, the reflow process forms the external electrical connectors 170 as homogeneous solder spheres. As shown, after the reflow process, each external electrical connector 170 has a height H2 from an uppermost surface of the external electrical connector 170 to the uppermost surface of the insulating material 145.

Further processing may then be performed to complete the package. For example, with reference to the structure of package 100 in FIGS. 1-8, a carrier substrate de-bonding may be performed to detach (de-bond) carrier substrate 20 from the package structure. In accordance with some embodiments, the de-bonding includes projecting a light such as a laser light or an UV light on release layer 22 so that release layer 22 decomposes under the heat of the light and carrier substrate 20 can be removed.

The structure can then be flipped over and placed on a tape and singulated. One of ordinary skill in the art will understand that many such package structures may be simultaneously formed on the carrier substrate 20, and hence, individual packages can be singulated from the other packages, such as by sawing or dicing.

Embodiments herein provide for forming external electrical connectors 170 with same heights H1 and/or with same heights H2 despite being located in regions of the integrated circuit die 26 having different UBM structure densities, i.e., different external electrical connector densities.

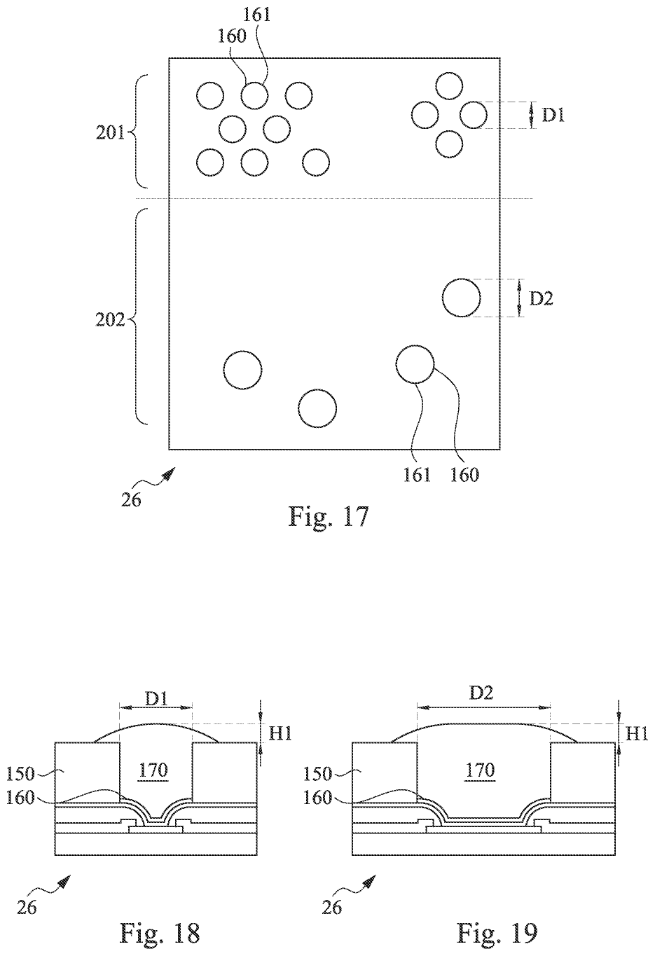

FIG. 17 provides a schematic overhead view of an integrated circuit die 26 including a first region 201 and a second region 202. FIG. 18 is a cross-sectional view of a UBM structure 160 in the first region 201, and FIG. 19 is a cross-sectional view of a UBM structure 160 in the second region 202. As shown in FIG. 17, UBM structures 160 are arranged more densely in the first region 201 than in the second region 202. For example, the first region 201 may be a dense region 201, and the second region 202 may be an isolated region. The first region 201 has a first ratio of UBM structures per unit area, and the second region 202 has a second ratio of UBM structures per unit area. As shown, the first ratio is greater than the second ratio.

It has been found that formation of external electrical connectors 170 over UBM structures 160 in dense regions 201 typically results in external electrical connectors 170 with relatively shorter heights (H1 in FIG. 13 and/or H2 in FIG. 16), and formation of external electrical connectors 170 over UBM structures 160 in isolated regions 202 results in external electrical connectors 170 with relatively taller heights (H1 in FIG. 13 and/or H2 in FIG. 16).

Embodiments herein counteract the tendency to form external electrical connectors 170 with different heights in dense regions 201 and isolated regions 202. Specifically. embodiments herein compensate for such tendency by changing the structure and/or layout of UBM structures 160 in at least one of the regions 201 and/or 202. As a result, the external electrical connectors 170 are formed with a same height in the dense regions 201 and isolated regions 202.

For example, in FIGS. 17 and 18, the UBM structures 160 in the dense region 201 are formed with a lateral width or critical dimension W1 that is equal to distance D1, while in FIGS. 17 and 19 the UBM structures 160 in the isolated region 202 are formed with a lateral width or critical dimension W1 that is equal to distance D2. As shown, distance D2 is greater than distance D1. In some embodiments, distance D1 or D2 is from about 1 to 20 micrometers, such as at least 1, at least 2, at least 3, at least 4, at least 5, at least 6, at least 7, at least 8, at least 9, at least 10, at least 11, at least 12, at least 13, at least 14, at least 15, at least 16, at least 17, at least 18, or at least 19 micrometers; and at most 2, at most 3, at most 4, at most 5, at most 6, at most 7, at most 8, at most 9, at most 10, at most 11, at most 12, at most 13, at most 14, at most 15, at most 16, at most 17, at most 18, at most 19, or at most 20 micrometers.

In some embodiments, distance DI is from 10 to 90% of distance D2. For example. distance D1 may be at least 10%, at least 20%, at least 30%, at least 40%, at least 50%, at least 60%, at least 70%, at least 80% or at least 90% of distance D2. In some embodiments, distance D1 may be at most 15%, at most 20%, at most 30%, at most 40%, at most 50%, at most 60%, at most 70%, at most 80%, at most 90% or at most 95% of distance D2.

As shown in FIGS. 18 and 19, the external electrical connectors 170 are formed with a same height H1 in the dense regions 201 and in isolated regions 202.

In FIGS. 17-19, all of the UBM structures 160 may be active UBM structures 161, such as UBM structures 61 in FIG. 8. Specifically, the active UBM structures 161 are electrically interconnected to other conductive structures in the die 26.

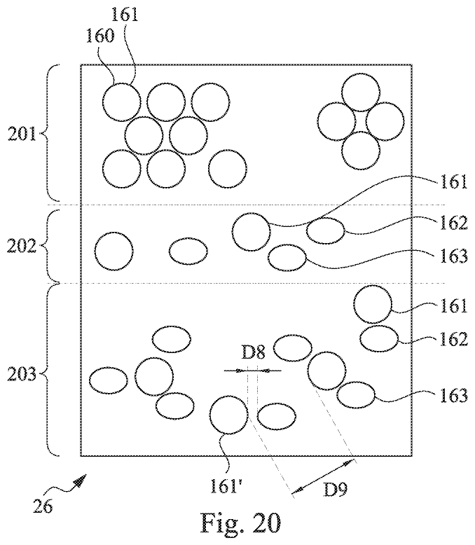

An alternative or additional embodiment is shown in FIGS. 20-23. FIG. 20 provides a schematic overhead view of an integrated circuit die 26 including a first dense region 201, a second isolated region 202, and a third intermediate region 203. As shown in FIG. 20. the integrated circuit die 26 is formed with active UBM structures 161, dummy UBM structures 162, such as dummy UBM structures 62 in FIG. 8, and dummy UBM structures 163, such as dummy UBM structures 63 in FIG. 8.

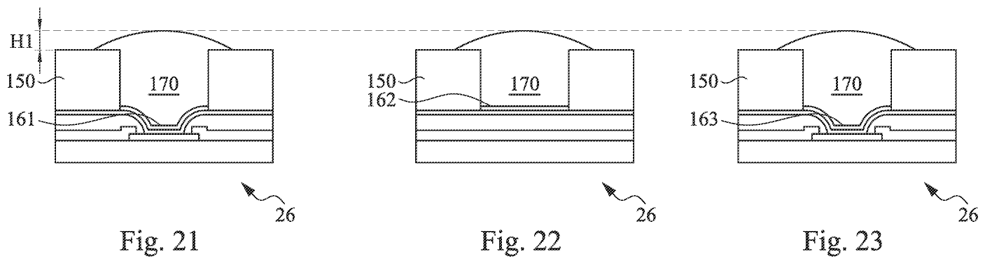

FIG. 21 is a cross-sectional view of an active UBM structure 161 in regions 201, 202 and 203. FIG. 22 is a cross-sectional view of an inactive or dummy UBM structure 162, which may be located in regions region 202 and 203. FIG. 23 is a cross-sectional view of an inactive or dummy UBM structure 163, which may be located in regions region 202 and 203.

As shown in FIG. 20, active UBM structures 161 are arranged more densely in the first region 201 than in the third region 203. Further, active UBM structures 161 are arranged more densely in the third region 203 than in the second region 202. The first region 201 has a first ratio of active UBM structures per unit area, the second region 202 has a second ratio of active UBM structures per unit area, and the third region 203 has a third ratio of active UBM structures per unit area. As shown, the first ratio is greater than the third ratio, and the third ratio is greater than the second ratio.

As further shown, inactive or dummy UBM structures 162 and/or 163 are provided in the second region 202 and third region 203 to increase the density of total UBM structures 160 therein. As a result, across regions 201, 202, and 203, the difference between the ratios of total UBM structures 160 (including active and dummy structures) is less than the difference between the ratios of active UMB structures 161. For example, the first region 201 may have a first ratio of total UMB structures 160 per unit area, the second region 202 may have a second ratio of active UMB structures 160 per unit area, and the third region 203 may have a third ratio of active UMB structures 160 per unit area. The first ratio of total UMB structures 160 per unit area, the second ratio of active UMB structures 160 per unit area, and the third ratio of active UMB structures 160 per unit area may be equal, or may be within 1%, within 2%, within 3%, within 4%, within 5%, within 10%, within 15% or within 20%. In some embodiments, localized subregions within the regions 201, 202, and 203 have equal ratios of active UMB structures 160 per unit area, or such ratios are within 1%, within 2%, within 3%, within 4%, within 5%, within 10%, within 15% or within 20%.

Another approach to evaluating the relative density or isolation of an active UBM structure 161 involves the inter-structure distance from each active UBM structure 161 to a respective nearest adjacent active UBM structure 161. As shown in FIG. 20, a selected active UBM structure 161′ in region 202 is located at an inter-active-structure distance D9 from a relative nearest adjacent active UBM structure 161.

In dense region 201, active UBM structures 161 may be located at a maximum first inter-active-structure distance from a respective nearest adjacent active UBM structure 161. In isolated region 202, active UBM structures 161 may be located at a second maximum first inter-active-structure distance from a respective nearest adjacent active UBM structure 161. In intermediate region 203, active UBM structures 161 may be located at a third maximum first inter-active-structure distance from a respective nearest adjacent active UBM structure 161. In some embodiments, the first maximum first inter-active-structure distance is less than the third maximum first inter-active-structure distance and less than the second maximum first inter-active-structure distance. In some embodiments, the third maximum first inter-active-structure distance is less than the second maximum first inter-active-structure distance.

In dense region 201, active UBM structures 161 may be located at a minimum first inter-active-structure distance from a respective nearest adjacent active UBM structure 161. In isolated region 202, active UBM structures 161 may be located at a second minimum first inter-active-structure distance from a respective nearest adjacent active UBM structure 161. In intermediate region 203, active UBM structures 161 may be located at a third minimum first inter-active-structure distance from a respective nearest adjacent active UBM structure 161. In some embodiments, the first minimum first inter-active-structure distance is less than the third minimum first inter-active-structure distance and less than the second minimum first inter-active-structure distance. In some embodiments, the third minimum first inter-active-structure distance is less than the second minimum first inter-active-structure distance.

As shown in FIG. 20, inactive or dummy UBM structures 162 and/or 163 are provided in the second region 202 and third region 203 to reduce the distance between each active UBM structure 161 and the nearest UBM structure 160 (including inactive or dummy UBM structures 162 and/or 163). As a result, the isolation of each active UBM structure 161 is reduced. For example, a dummy UBM structure 162 and/or 163 is located at an inter-structure distance D8 from the selected active UBM structure 161′. As shown, inter-structure distance D8 is less than inter-active-structure distance D9. Further, inter-structure distance D8 may be equal or less than a selected threshold for inter-structure distances. For example, a threshold for inter-structure distances in regions 202 and 203 may be selected based on the inter-active-structure distances in region 201, such as based on an average or mean inter-active-structure distance in region 201, a maximum inter-active-structure distance in region 201, or a minimum inter-active-structure distance in region 201.

In some embodiments, each inter-structure distance D8 in regions 202 and 203 is equal to or less than a maximum inter-active-structure distance in region 201. In some embodiments, each inter-structure distance D8 in regions 202 and 203 is within 1%, within 2%, within 3%, within 4%, within 5%, with 10% within 15%, or within 20% of a maximum inter-active-structure distance in region 201.

In some embodiments, each inter-structure distance D8 in regions 202 and 203 is equal to an average or mean inter-active-structure distance in region 201. In some embodiments, each inter-structure distance D8 in regions 202 and 203 is within 1%, within 2%, within 3%, within 4%, within 5%, with 10% within 15%, or within 20% of an average or mean inter-active-structure distance in region 201.

In some embodiments, each active UBM structure 161 within regions 202 and 203 that is located at an inter-active-structure distance D9 from a nearest active UBM structure 161 that is greater than a selected threshold is provided with a nearer inactive or dummy UBM structure or structures 162 and/or 163 to reduce the relative isolation of the active UBM structure 161. By providing inactive or dummy UBM structures 162 and/or 163 in the second region 202 and third region 203, relative isolation of each active UBM structure 161 in the second region 202 and third region 203 is reduced.

By reducing the relative isolation of each UBM structure 160, i.e., no UBM structure 160 is located farther from a respective nearest adjacent UBM structure by a distance greater than the selected threshold, the variance in heights between external electrical connectors 170 formed over the UBM structures 160 is reduced or eliminated.

As shown in FIGS. 21-23, the external electrical connectors 170 formed over active UBM structures 161, over dummy UBM structures 162, and over dummy UBM structures 163 each are formed with an uppermost surface at a same height H1 over the uppermost surface of the photo resist 150.

It is noted that the embodiment of FIGS. 17-19 limits the vertical height of the external electrical connectors 170 by forming UBM pads 160 with different critical dimensions, and the embodiment of FIGS. 20-23 limits the vertical height of the external electrical connectors 170 by forming dummy UBM pads 162-163 adjacent to relative isolated active UBM pads 161. Further, it is noted that dies 26 may be provided with a combination of the embodiments of FIGS. 17-19 and FIGS. 20-23 such that in some embodiments UBM pads 160 are formed with different critical dimensions and dummy UBM pads are formed to reduce the isolation of relatively isolated active UBM pads.

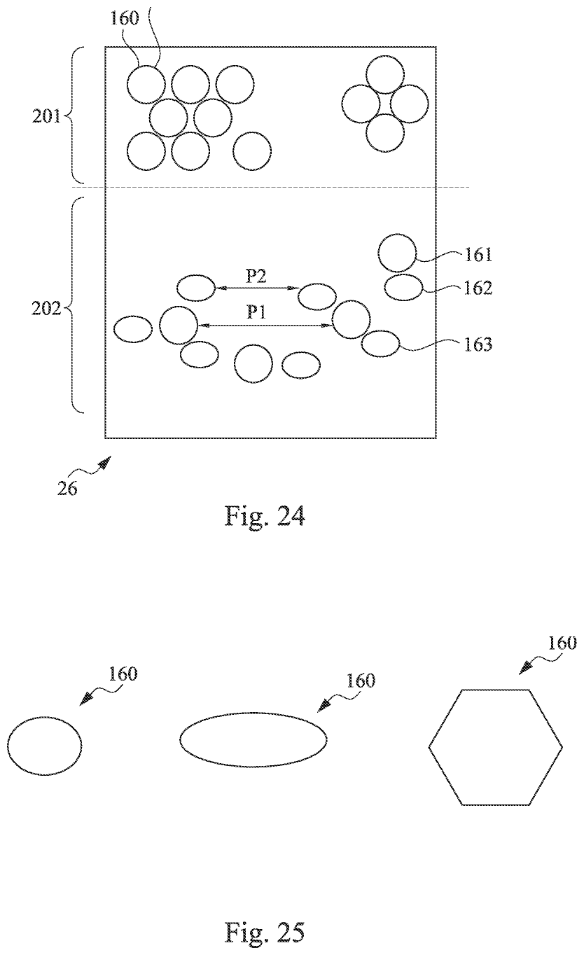

Referring now to FIG. 24, processing for forming active UBM structures 161 and processing for forming dummy UBM structures 162 and/or 163 is further described. During the formation of active UBM structures 161, the process may use a first pitch P1. However, formation of the dummy UBM structures 162 and/or 163 may be performed with a second pitch P2, different from the first pitch P1. As a result, the formation process may be smoother and may prevent cavity defects.

FIG. 25 provides an overhead view of UBM structures 160. As shown, UBM structures 160 may be provided with a circular shape, an oval shape, or a hexagonal shape. The UBM structures 160 are not limited to circular, oval, or hexagonal shapes. Specifically, the UBM structures 160 may be formed with any suitable shape, including triangular, square, rectangular, pentagonal, octagonal, irregular, etc. Further, it is noted that each active UBM structure 161, each dummy UBM structure 162, and each dummy UBM structure 163 may be formed with any selected shape independent of the shapes of other active UBM structures 161. dummy UBM structures 162, and dummy UBM structures 163 on the die 26.

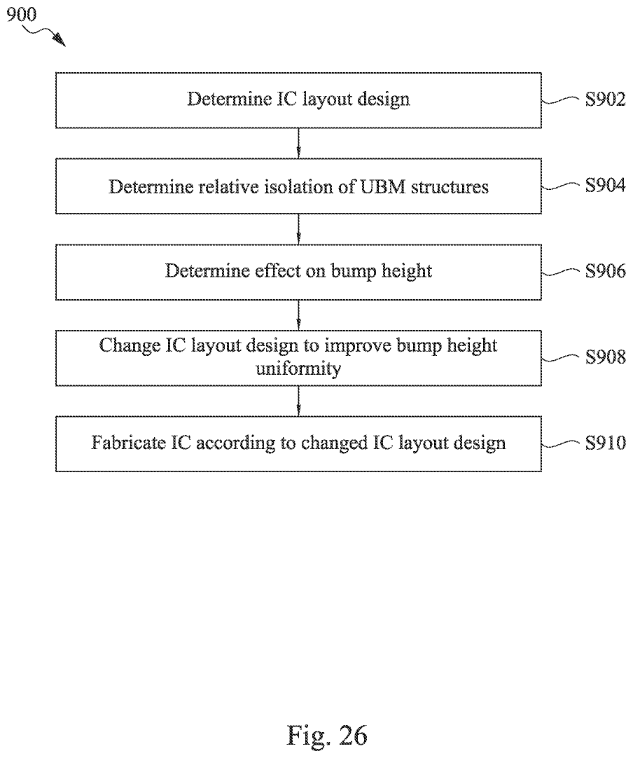

FIG. 26 provides a flow chart of a method 900. As shown, method 900 includes determining an integrated circuit (IC) layout design at operation S902.

Method 900 further includes at operation S904 determining the relative isolation of UBM structures. For example, the IC layout design may include a dense region including densely arranged external electrical connectors on under bump metal (UBM) structures and an isolated region including isolated external electrical connectors on under bump metal (UBM) structures. Determining the relative isolation of UBM structures may include determining the inter-active-structure distance of each active UBM structure.

At operation S906, the method 900 determines the effect on bump height resulting from the relative isolation of UBM structures. For example, method 900 may determine that external electrical connectors formed over isolated UBM structures will be formed with an increased height relative to external electrical connectors formed over densely packed UBM structures. Determining the effect on bump height resulting from the relative isolation of UBM structures may include referring to a stored library of known height effects based on inter-active-structure distances or device density or isolation.

At operation S908, method 900 changes the IC layout design to improve bump height uniformity. For example, the IC layout design may be changed to provide the densely arranged external electrical connectors on under bump metal (UBM) pads with a first height, and to provide the isolated external electrical connectors on under bump metal (UBM) pads with a second height equal to the first height. In other words, operation S908 may limit the external electrical connectors to a pre-selected vertical height, i.e., the first height.

For example, at operation S908, method 900 may increase the critical dimension of UBM structures, and/or the openings over UBM structures, in isolated regions. Additionally or alternatively, at operation S908, method 900 may decrease the critical dimension of UBM structures, and/or the openings over UBM structures, in dense regions. Additionally or alternatively, at operation S908, method 900 may add dummy UBM structures to the IC layout design to reduce the inter-structure distance of UBM structures in isolated regions.

At operation S910, method 900 fabricates the integrated circuit (IC) according to the changed IC layout design. Fabricating the IC includes forming the under bump metal (UBM) pads in the dense region and in the isolated region; and forming the external electrical connectors over the under bump metal (UBM) pads in the dense region and in the isolated region.

As a result of operation S908, the IC is fabricated with improved bump height uniformity. For example, the external electrical connectors in the IC may be formed with a same height, or with heights within 1%, within 2%, within 3%, within 4%, within 5%, within 10%, or within 20% of one another, whether in dense or isolated regions.

In an embodiment, a method includes forming a semiconductor die having under bump metal (UBM) pads in a dense region and in an isolated region; forming external electrical connectors in contact with the UBM pads; and limiting the external electrical connectors to a pre-selected vertical height.

In some embodiments, the method further includes forming openings over the UBM pads; wherein forming the external electrical connectors in contact with the UBM pads includes forming the external electrical connectors in the openings.

In some embodiments of the method, forming the external electrical connectors includes dropping solder balls in the openings.

In some embodiments of the method, limiting the external electrical connectors to a pre-selected vertical height includes forming the openings over the UBM pads in the dense region with a first critical dimension; and forming the openings over the UBM pads in the isolated region with a second critical dimension greater than the first critical dimension, and forming the external electrical connectors in contact with the UBM pads includes forming the external electrical connectors in the openings.

In some embodiments of the method, limiting the external electrical connectors to a pre-selected vertical height includes forming the UBM pads in the dense region with a first critical dimension; and forming the UBM pads in the isolated region with a second critical dimension greater than the first critical dimension.

In some embodiments of the method, each UBM pad in the dense region is separated from a nearest adjacent UBM pad by a first distance; at least one UBM pad in the isolated region is separated from a relative nearest adjacent UBM pad by a second distance greater than the first distance; and limiting the external electrical connectors to the pre-selected vertical height includes forming a dummy pad at a third distance from the at least one UBM pad in the isolated region, wherein the third distance is less than the second distance; and forming an external electrical connector in contact with the dummy pad while forming the external electrical connectors in contact with the UBM pads. In some embodiments, the third distance is within 20% of the first distance. In some embodiments, the third distance is equal to the first distance.

In some embodiments of the method, each UBM pad in the dense region is separated from a nearest adjacent UBM pad by a first distance; at least one UBM pad in the isolated region is separated from a relative nearest adjacent UBM pad by a second distance greater than the first distance; and limiting the external electrical connectors to the pre-selected vertical height includes forming the UBM pads in the dense region with a first critical dimension; forming the UBM pads in the isolated region with a second critical dimension greater than the first critical dimension; forming a dummy pad at a third distance from the at least one UBM pad in the isolated region, wherein the third distance is less than the second distance; and forming an external electrical connector in contact with the dummy pad while forming the external electrical connectors in contact with the UBM pads.

In another embodiment, a method includes determining an integrated circuit layout design, wherein the integrated circuit layout design comprises a dense region including densely arranged external electrical connectors on under bump metal (UBM) pads and an isolated region including isolated external electrical connectors on under bump metal (UBM) pads, wherein determining the integrated circuit layout design comprises providing the densely arranged external electrical connectors on under bump metal (UBM) pads with a first height, and wherein determining the integrated circuit layout design comprises providing the isolated external electrical connectors on under bump metal (UBM) pads with a second height equal to the first height; forming the under bump metal (UBM) pads in the dense region and in the isolated region; and forming the external electrical connectors over the under bump metal (UBM) pads in the dense region and in the isolated region.

In some embodiments of the method, determining the integrated circuit layout design includes providing the under bump metal (UBM) pads in the dense region with a first lateral critical dimension and providing the under bump metal (UBM) pads in the isolated region with a second lateral critical dimension different from the first lateral critical dimension. In some embodiments, the second lateral critical dimension is greater than the first lateral critical dimension.

In some embodiments of the method, determining the integrated circuit layout design includes providing dummy under bump metal (UBM) pads in the isolated region.

In some embodiments of the method, the UBM pads in the dense region, the UBM pads in the isolated region, and the dummy UBM pads have a same lateral critical dimension.

In some embodiments of the method, the dense region has a first ratio of UBM pads per unit area; the isolated region has a combined ratio of UBM pads and dummy UBM pads per unit area; and the first ratio is equal to the combined ratio.

In another embodiment, a semiconductor die includes a dense region including first under bump metal (UBM) pads, wherein the dense region has a first ratio of first UBM pads per unit area; first external electrical connectors in contact with the first UBM pads, wherein each first external electrical connector has a first vertical height; an isolated region including second under bump metal (UBM) pads, wherein the isolated region has a second ratio of second UBM pads per unit area, wherein the first ratio is greater than the second ratio; and second external electrical connectors in contact with the second under bump metal (UBM) pads, wherein each second external electrical connector has a second vertical height; wherein the semiconductor die is configured to have the first vertical height equal the second vertical height.

In some embodiments of the semiconductor die, the first external electrical connectors have a first lateral critical dimension, and the semiconductor die is configured to have the first vertical height equal the second vertical height by providing the second external electrical connectors with a second lateral critical dimension different from the first lateral critical dimension.

In some embodiments of the semiconductor die, the second lateral critical dimension is greater than the first lateral critical dimension.

In some embodiments, the semiconductor die includes a dielectric layer overlying the dense region and the isolated region, openings are formed in the dielectric overlying the first UBM pads and overlying the second UBM pads, and the openings limit the first external electrical connectors to the first lateral critical dimension and limit the second external electrical connectors to the second lateral critical dimension.

In some embodiments of the semiconductor die, the semiconductor die is configured to have the first vertical height equal the second vertical height by including dummy under bump metal (UBM) pads in the isolated region, wherein the isolated region has a third ratio of total UBM pads, comprising second UBM pads and dummy UBM pads, per unit area, wherein the third ratio is greater than the second ratio.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a semiconductor die having under bump metal (UBM) pads in a dense region and in an isolated region;
forming external electrical connectors in contact with the UBM pads; and
limiting the external electrical connectors to a pre-selected vertical height.

2. The method of claim 1, further comprising:
forming openings over the UBM pads; wherein forming the external electrical connectors in contact with the UBM pads comprises forming the external electrical connectors in the openings.

3. The method of claim 2, wherein forming the external electrical connectors comprises dropping solder balls in the openings.

4. The method of claim 2, wherein limiting the external electrical connectors to a pre-selected vertical height comprises:
forming the openings over the UBM pads in the dense region with a first critical dimension; and
forming the openings over the UBM pads in the isolated region with a second critical dimension greater than the first critical dimension,
wherein forming the external electrical connectors in contact with the UBM pads comprises forming the external electrical connectors in the openings.

5. The method of claim 1, wherein limiting the external electrical connectors to a pre-selected vertical height comprises:
forming the UBM pads in the dense region with a first critical dimension; and
forming the UBM pads in the isolated region with a second critical dimension greater than the first critical dimension.

6. The method of claim 1, wherein:
each UBM pad in the dense region is separated from a nearest adjacent UBM pad by a first distance;
at least one UBM pad in the isolated region is separated from a relative nearest adjacent UBM pad by a second distance greater than the first distance; and
limiting the external electrical connectors to the pre-selected vertical height comprises:
forming a dummy pad at a third distance from the at least one UBM pad in the isolated region, wherein the third distance is less than the second distance; and
forming an external electrical connector in contact with the dummy pad while forming the external electrical connectors in contact with the UBM pads.

7. The method of claim 6, wherein the third distance is within 20% of the first distance.

8. The method of claim 6, wherein the third distance is equal to the first distance.

9. The method of claim 1, wherein:
each UBM pad in the dense region is separated from a nearest adjacent UBM pad by a first distance;
at least one UBM pad in the isolated region is separated from a relative nearest adjacent UBM pad by a second distance greater than the first distance; and
limiting the external electrical connectors to the pre-selected vertical height comprises:
forming the UBM pads in the dense region with a first critical dimension;
forming the UBM pads in the isolated region with a second critical dimension greater than the first critical dimension;
forming a dummy pad at a third distance from the at least one UBM pad in the isolated region, wherein the third distance is less than the second distance; and
forming an external electrical connector in contact with the dummy pad while forming the external electrical connectors in contact with the UBM pads.

10. A method comprising:
determining an integrated circuit layout design, wherein the integrated circuit layout design comprises a dense region including densely arranged external electrical connectors on under bump metal (UBM) pads and an isolated region including isolated external electrical connectors on under bump metal (UBM) pads, wherein determining the integrated circuit layout design comprises providing the densely arranged external electrical connectors on under bump metal (UBM) pads with a first height, and wherein determining the integrated circuit layout design comprises providing the isolated external electrical connectors on under bump metal (UBM) pads with a second height equal to the first height;
forming the under bump metal (UBM) pads in the dense region and in the isolated region; and
forming the external electrical connectors over the under bump metal (UBM) pads in the dense region and in the isolated region.

11. The method of claim 10 wherein determining the integrated circuit layout design comprises providing the under bump metal (UBM) pads in the dense region with a first lateral critical dimension and providing the under bump metal (UBM) pads in the isolated region with a second lateral critical dimension different from the first lateral critical dimension.

12. The method of claim 11 wherein the second lateral critical dimension is greater than the first lateral critical dimension.

13. The method of claim 10 wherein determining the integrated circuit layout design comprises providing dummy under bump metal (UBM) pads in the isolated region.

14. The method of claim 13 wherein the UBM pads in the dense region, the UBM pads in the isolated region, and the dummy UBM pads have a same lateral critical dimension.

15. The method of claim 13, wherein:
the dense region has a first ratio of UBM pads per unit area;
the isolated region has a combined ratio of UBM pads and dummy UBM pads per unit area; and
the first ratio is equal to the combined ratio.

16. A semiconductor die, comprising:
a dense region including first under bump metal (UBM) pads, wherein the dense region has a first ratio of first UBM pads per unit area;
first external electrical connectors in contact with the first UBM pads, wherein each first external electrical connector has a first vertical height;
an isolated region including second under bump metal (UBM) pads, wherein the isolated region has a second ratio of second UBM pads per unit area, wherein the first ratio is greater than the second ratio; and
second external electrical connectors in contact with the second under bump metal (UBM) pads, wherein each second external electrical connector has a second vertical height;
wherein the semiconductor die is configured to have the first vertical height equal the second vertical height.

17. The semiconductor die of claim 16, wherein the first external electrical connectors have a first lateral critical dimension, and wherein the semiconductor die is configured to have the first vertical height equal the second vertical height by providing the second external electrical connectors with a second lateral critical dimension different from the first lateral critical dimension.

18. The semiconductor die of claim 17, wherein the second lateral critical dimension is greater than the first lateral critical dimension.

19. The semiconductor die of claim 17, further comprising:
a dielectric layer overlying the dense region and the isolated region, wherein openings are formed in the dielectric layer overlying the first UBM pads and overlying the second UBM pads, and wherein the openings limit the first external electrical connectors to the first lateral critical dimension and limit the second external electrical connectors to the second lateral critical dimension.

20. The semiconductor die of claim 16, wherein the semiconductor die is configured to have the first vertical height equal the second vertical height by comprising dummy under bump metal (UBM) pads in the isolated region, wherein the isolated region has a third ratio of total UBM pads, comprising second UBM pads and dummy UBM pads, per unit area, wherein the third ratio is greater than the second ratio.
